(19) United States
(12) Patent Application Publication
(10) Pub. No.: US 2011/0253989 A1
(43) Pub. Date: Oct. 20, 2011

(54) ORGANIC ELECTRONIC CIRCUIT

(75) Inventors: Andreas Ullmann, Zirndorf (DE); Klaus Schmidt, Ruckersdorf (DE)

(73) Assignee: POLYIC GMBH & CO. KG, Furth (DE)

(21) Appl. No.: 13/139,564

(22) PCT Filed: Dec. 14, 2009
(86) PCT No.: PCT/EP2009/008939

§ 371 Date: Jul. 6, 2011

(30) Foreign Application Priority Data
Dec. 15, 2008 (DE) 102008061928.0
Dec. 14, 2009 (EP) PCT/EP2009/008939

(51) Int. Cl. H01L 51/10; H01G 4/30

(52) U.S. Cl. 257/40; 361/301.4; 257/E51.002

(57) ABSTRACT

The invention concerns an organically electronic circuit (1, 2, 3), having a main substrate (80, 80a, 80b) and an organic electronic assembly (10, 11, 12) in the form of a multilayer film body with electrically conducting and semiconducting functional layers (101, 103, 105). In a first region (90) of the circuit (1, 2, 3) one of the electrically conducting functional layers (101, 105) of the electronic assembly (10, 11, 12), is shaped in the form of an electrode layer. Electrodes for organic field effect transistors or diodes are formed in that electrically conducting functional layer which is in the form of a first capacitor plate (201). In a second region (91) of the circuit (1, 2, 3) one of the electrically conducting functional layers (101, 105) of the organic electronic assembly (10, 11, 12), is in the form of an electrode layer. Electrodes for organic field effect transistors or diodes are shaped in that electrically conducting functional layer which is shaped in the form of a second capacitor plate (211). The main substrate (80, 80a, 80b) has an electrically conductive layer shaped in the form of a third capacitor plate (50). The third capacitor plate (50), and the electronic assembly (10, 11, 12) and the main substrate (80, 80a, 80b) are so laminated together that the third capacitor plate (50) at least partially overlaps the first capacitor plate (201) and the second capacitor plate (211) respectively, forming a capacitor.

The invention concerns an organically electronic circuit.

As described for example in DE 103 49 027 B4 organically electronic circuits are used for example in organic RFID transponders (RFID=radio frequency identification). In particular RFID transponders are used for identification purposes, for example as a price tag, and for protecting goods and documents. Organically electronic circuits should therefore have a high level of flexibility and be of a small structural size but in that respect can nonetheless be mechanically loaded. The organically electronic circuits are products which are manufactured in mass production. The organically electronic circuits generally have a plurality of mutually superposed electrical functional layers which are arranged in succession and one upon the other.

Now the object of the invention is to provide an improved organically electronic circuit.

The object of the invention is attained by an organically electronic circuit which has a main substrate and an organic electronic assembly in the form of a multilayer film body which has one or more electrically conducting functional layers and one or more electrically semiconducting functional layers, wherein in a first region of the organically electronic circuit one of the one or more electrically conducting functional layers of the organic electronic assembly, which has an electrode layer of the electronic assembly in which one or more electrodes for one or more organic field effect transistors or organic diodes are formed, is further shaped in the form of a first capacitor plate which thus forms an integral component of the organic electronic assembly, and in a second region of the organically electronic circuit one of the one or more electrically conducting functional layers of the organic electronic assembly which has an electrode layer of the electronic assembly in which one or more electrodes for one or more organic field effect transistors or organic diodes are formed, is further shaped in the form of a second capacitor plate which thus forms an integrated component of the organic electronic assembly, the electronic circuit and the main substrate are laminated together, the main substrate has an electrically conductive layer which is shaped in the form of a third capacitor plate, and the third capacitor plate is so shaped and the electronic assembly and the main substrate are so laminated together that the third capacitor plate at least partially overlaps the first capacitor plate and the second capacitor plate respectively, and the first capacitor plate, the second capacitor plate and the third capacitor plate form a capacitor of the organically electronic circuit.

It has been found that the quality of the capacitors, which the organically electronic circuit has, is improved by such a configuration of the organically electronic circuit. In other words, the wastage caused by a defective production process is reduced and the manufacturing process enjoys cost advantages. The third capacitor plate as a component of the main substrate already improves the mechanical load-bearing capability of the organically electronic circuit, during manufacture. The main substrate with the third capacitor plate represents a substrate which is highly suited to the construction of the organic electronic assembly. Manufacture of the organic electronic assembly can be implemented using technologies such as printing, coating with a doctor blade or sputtering, which require extensive special equipment but afford cost advantages for mass production. It has been found that the conductive adhesives used for conventional contacting of the electronic assemblies produced by means of such a manufacturing technology lead to mechanically susceptible galvanic connections. The reason for that is that those conductive adhesives are no longer flexible in the hardened condition. The invention makes it possible to reduce the use of conductive adhesive for the production of the organically electronic circuit for it is possible to dispense with the use of a cost-intensive conductive adhesive in the production of the capacitor according to the invention comprising the three capacitor plates, wherein the first and second capacitor plates are each in the form of a respective electrode of a semiconductor component, for example an organic field effect transistor or an organic diode. It is possible with the organically electronic circuit according to the invention to implement improved circuits which have capacitors. The organically electronic circuit according to the invention is not only advantageous due to an improved production process but it also has an improved failure rate, that is to say the probability of defective lacquer layers occurring, which lead to leakage currents in the capacitors and make them unusable, is reduced.

The organically electronic circuit in accordance with a preferred embodiment has an organic electronic assembly which fundamentally differs in the materials and production processes used, from a silicon chip which is usually employed for integrated circuits. The electrically conducting, semiconducting and/or insulating functional layers of that organic electronic assembly are formed by layers of a multilayer film body, which are applied by printing, coating with a doctor blade, vapor deposition or sputtering. The electrically conducting, semiconducting and/or insulating functional layers of the organic electronic assembly are in that case built up on a flexible carrier substrate comprising a plastic film and/or paper of a thickness of between 10 μm and 100 μm, in contrast to a silicon chip. That film thus forms the carrier substrate of the integrated electronic circuit, that is to say the organic electronic assembly, instead of a silicon dioxide wafer in an integrated electronic circuit formed by a silicon chip. The semiconducting functional layers of that circuit are preferably applied in a solution and thus applied for example by printing, spraying, coating with a doctor blade or casting. In that respect, preferably semiconducting functional polymers such as polythiophene, polyterthiophene, polyfluorene, pentacene, tetracene, oligothothene, inorganic silicon embedded in a polymer matrix, nano-silicon or polyarylamine can be considered as materials of the semiconducting functional layers, but inorganic materials which can be applied in solution or by sputtering or vapor deposition, for example ZnO, a-Si can also be considered. The first and second capacitor plates form an integral component of that organic electronic assembly and are shaped in one or more different electrode layers of the electronic assembly, in which moreover one or more electrodes for one or more organic field effect transistors or organic diodes are shaped. The first and second capacitor plates thus form an integral component of the integrated electronic circuit formed by the electrically conducting, semiconducting and/or insulating functional layers of the multilayer film body. A subregion of an interconnected electrically conductive region of an electrode layer of the organically electronic circuit thus forms an electrode of an organic field effect transistor or an organic diode. A region of the main substrate which is the carrier of the organically electronic circuit has an electrically conductive region. That region has a third capacitor plate which partially overlaps at least the first and second capacitor plates, forming a capacitor. Such a region of the electrically conductive layer of the organic electronic assembly forms on the one hand an electrode of an active organically electrical component and thus for example is in contact with a semiconducting layer of the organic electronic assembly and forms on the other hand a capacitor plate for producing a capacitor by means of the further capacitor plate of the organic electronic assembly and the third capacitor plate of the main substrate, that is to say so that the organically electronic circuit forms a capacitor by means of the three capacitor plates.

Here the term organic electronic component is used to denote an electrical component predominantly consisting of organic material, in particular comprising at least 90% by weight of organic material. In that case an individual organic component is made up of different layers having an electrical function, in particular in the form of thin layers which are not self-supporting, and also at least the regions of a carrier substrate, that are to be associated with the layers, the layers being disposed on the carrier substrate. In that case the individual layers can be formed from organic or inorganic material, wherein only organic, only inorganic, or organic and inorganic layers can be used in combination to form an organic component. Thus an electrical component including an organic carrier substrate and exclusively inorganic layers with an electrical function, by virtue of the usually large mass of carrier substrate in comparison with the mass of the functional layers, is viewed overall as an organic component.

In a preferred embodiment of the invention the third capacitor plate completely overlaps the first and second regions. The capacitance of the capacitor is increased thereby.

In a preferred embodiment of the invention the third capacitor plate is of a strip shape. In particular the third capacitor plate can be in a strip shape in the form of a narrow strip of a length which is at least twice greater than a width of the strip. That provides for optimum utilisation of the area of the functional layers of the multilayer film body.

In a preferred embodiment of the invention the first capacitor plate and the second capacitor plate are shaped in the same electrically conducting functional layer of the one or more electrically conducting functional layers of the electronic assembly.

In a preferred embodiment it can also be provided that the first and second capacitor plates are shaped in different electrically conducting functional layers of the one or more electrically conducting functional layers of the electronic assembly.

In a preferred embodiment of the invention the first region of the organically electronic circuit and the second region of the organically electronic circuit are so associated with each other that the first capacitor plate and the second capacitor plate are spaced from each other at less than 100 μm. Preferably the first capacitor plate and the second capacitor plate are spaced from each other at a spacing of between 5 μm and 10 μm.

An arrangement of the first, second and third capacitor plates provides that fewer unwanted currents are induced by adjacent components in the capacitor and the signal quality of the organically electronic circuit is improved.

In a preferred embodiment of the invention the first capacitor plate, the second capacitor plate and/or the third capacitor plate are of a large area. It is possible for the first capacitor plate, the second capacitor plate and/or the third capacitor plate each to be of an area of between 4 mm² and 100 mm².

In a preferred embodiment of the invention an insulation layer is arranged between the first capacitor plate and the third capacitor plate, as well as between the second capacitor plate and the third capacitor plate. The insulation layer preferably overlaps completely the third capacitor plate and/or the first and second capacitor plates.

In a preferred embodiment of the invention the insulation layer comprises an inorganic dielectric layer of a layer thickness of between 5 and 100 nm. The inorganic dielectric layer is preferably applied to the surface of the electrically conducting layer of the main substrate.

In addition an adhesive layer is preferably arranged between the insulation layer and the electronic assembly. The layer thickness of the adhesive layer is preferably less than 1 μm, further preferably less than 500 nm.

The inorganic dielectric layer is preferably applied to the surface of the electrically conducting layer of the main substrate by means of a coating process, for example by means of vapor deposition or sputtering. In that case the inorganic dielectric layer preferably comprises silicon dioxide.

In addition it is also possible for the inorganic dielectric layer to be formed by a metal oxide layer which is produced by surface oxidation of the electrically conductive layer of the main substrate, which in this case comprises a metal. In this case the thickness of the metal oxide layer is between 5 and 10 nm.

Further in a preferred embodiment of the invention the insulation layer comprises an electrically non-conducting tough plastic. The plastic can be an electrically non-conducting tough plastic film or an electrically non-conducting tough plastic lacquer.

The mechanically tough insulation film increases on the one hand the capacitance of the capacitor while on the other hand the organically electronic circuit has a better mechanical load-bearing capability. The multilayer film body nonetheless has a high level of flexibility. In production and also in use of the organic electronic circuit the probability of leakage currents occurring between the third and the first or the second capacitor plate is reduced by means of the tough insulation film. The occurrence of leakage currents endangers proper operability of the organically electronic circuit.

In a preferred embodiment of the invention the third capacitor plate is in the form of a metal film. The metal film can comprise one or more metals selected from the group of Al (Al=aluminum), Cu (Cu=copper), and in particular the metal film can have a metal alloy.

In a preferred embodiment of the invention the first capacitor plate, the second capacitor plate and/or the third capacitor plate comprise a material selected from the group Al (Al=aluminum, Cu (Cu=copper), Ag (Ag=silver), Au (Au=gold), Fe (Fe=iron) or conductive polymers or conductive silver or carbon black.

In a preferred embodiment of the invention the first capacitor plate, the second capacitor plate and/or the third capacitor plate are of a thickness of between 10 nm and 100 nm and preferably between 1 μm and 50 μm.

In a preferred embodiment of the invention the organically electronic circuit has a first adhesive layer between the third capacitor plate and the insulation layer. It can also be provided that the organically electronic circuit has a second adhesive layer between the first capacitor plate and the insulation layer and between the second capacitor plate and the insulation layer.

It is possible for the first adhesive layer and/or the second adhesive layer to have a plurality of adhesive dots.

In a preferred embodiment of the invention the first adhesive layer and/or the second adhesive layer is dielectric. The first adhesive layer and/or the second adhesive layer has a relative dielectric constant of between 2 and 4. The first and/or second adhesive layers can thus increase the capacitance of the capacitor without the structural height thereof being increased.

In a preferred embodiment of the invention the first adhesive layer and/or the second adhesive layer is of thickness of between 0.5 μm and 20 μm, and is preferably 1 μm.

In a preferred embodiment of the invention the insulation layer is dielectric and has a relative dielectric constant of between 2 and 7, wherein the insulation layer preferably comprises PET (PET=polyethyleneterephthalate), PP (PP=polypropylene) and/or polyamide. Preferably the relative dielectric constant of the insulation layer is between 2.3 (PP) and 3.2 (PET).

In a preferred embodiment of the invention the insulation layer is of a thickness of between 0.9 μm and 10 μm, and is preferably 1.8 μm.

In a preferred embodiment of the invention the insulation layer is in the form of a plastic film. Preferably the plastic film includes a polyethyleneterephthalate film, that is to say a PET film, and/or a polypropylene film, that is to say a PP film. It is possible for the insulation layer to have one or more plastic films.

In a preferred embodiment of the invention the main substrate has a substrate layer. The substrate layer preferably comprises paper and/or a plastic film, in particular PET or PP.

In a preferred embodiment of the invention the organic electronic assembly, in one or more third regions of the organically electronic circuit, has a respective one of the one or more electrically conducting functional layers. That respective one of the one or more electrically conducting functional layers is in the form of an electrode layer of the electronic assembly. One or more electrodes for one or more organic field effect transistors or organic diodes are shaped in that electrode layer. That respective one of the one or more electrically conducting functional layers is further shaped in the form of a further first capacitor plate. Those one or more first capacitor plates thus form an integral component of the organically electronic circuit. In one or more fourth regions of the organically electronic circuit the organic electronic assembly has a respective one of the one or more electrically conducting functional layers. That respective one of the one or more electrically conducting functional layers is in the form of an electrode layer of the electrode assembly. One or more electrodes for one or more organic field effect transistors or diodes are shaped in that electrode layer. That respective one of the one or more electrically conducting functional layers is further shaped in the form of a further second capacitor plate. The one or more further second capacitor plates thus form an integrated component of the organically electronic circuit. The main substrate has an electrically conductive layer. The electrically conductive layer is shaped in the form of one or more further third capacitor plates. Each of the further one or more third capacitor plates is so shaped and the organic electronic assembly and the main substrate are so laminated to each other that the respective further third capacitor plate at least partially overlaps the respective further first capacitor plate and the respective further second capacitor plate. The respective further first capacitor plate, the respective further second capacitor plate and the respective further third capacitor plate respectively form a further capacitor of the organically electronic circuit.

It is possible in that way to produce organically electronic circuits which implement one or more capacitors having three capacitor plates. It is possible that, in configurations according to the invention, the further first and further second capacitor plates are formed in the same or in different functional layers of the organic electronic assembly.

In a preferred embodiment of the invention the organically electronic circuit has a coil. The coil is arranged in the main substrate. The coil can be in the form of an antenna coil of an antenna oscillator circuit of an RFID transponder.

In a preferred embodiment it can be provided that the organically electronic circuit has a coil. The coil has two contacts. The two contacts of the coil are in the form of a first plate, that is to say a beginning plate, and a second plate, that is to say an end plate. In one or two of the electrically conducting one or more functional layers the electronic assembly has a further first plate, that is to say a further first capacitor plate, and a further second plate, that is to say a further second capacitor plate. The first plate is disposed in at least partially overlapping relationship with the further first plate. The second plate is disposed in at least partially overlapping relationship with the further second plate. In each case the first plate with the further first plate and the second plate with the further second plate form a respective capacitor. The coil can be capacitively coupled to the electronic circuit by means of those two capacitors.

In a preferred embodiment of the invention the organic electronic assembly has a plurality of organic components. The plurality of organic components are selected from the group of organic resistor, organic capacitor, organic diode and/or organic field effect transistor.

In a preferred embodiment of the invention it is provided that the organically electronic circuit has a rectifying assembly.

In a preferred configuration of the invention the organically electronic circuit is an RFID transponder.

The invention is described by way of example hereinafter by means of several embodiments with reference to the accompanying drawings.

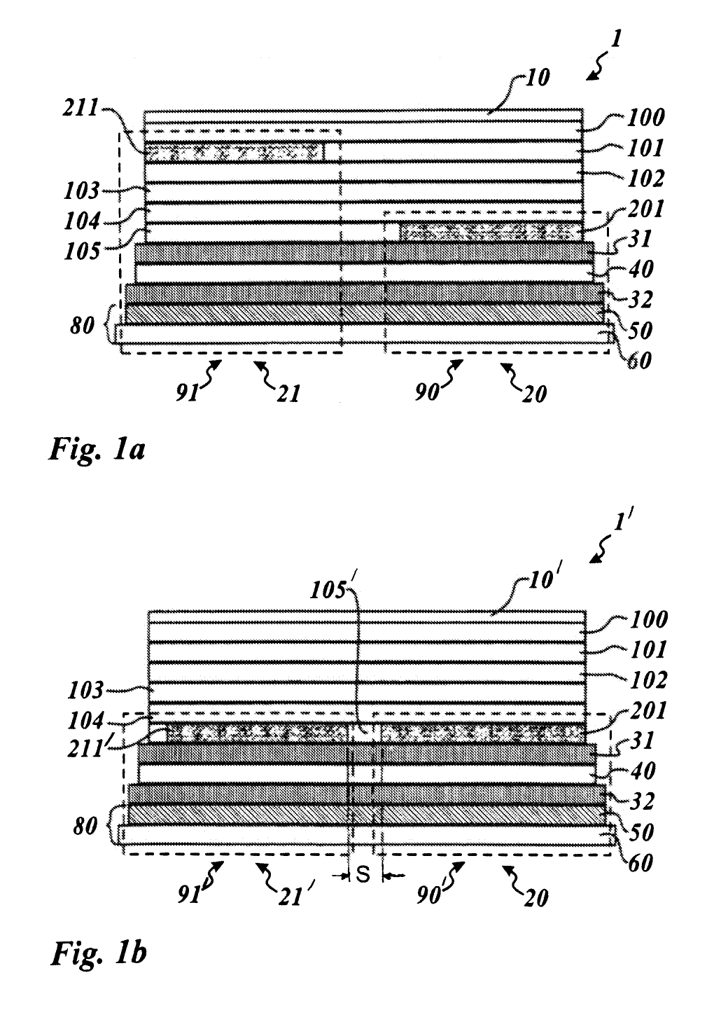

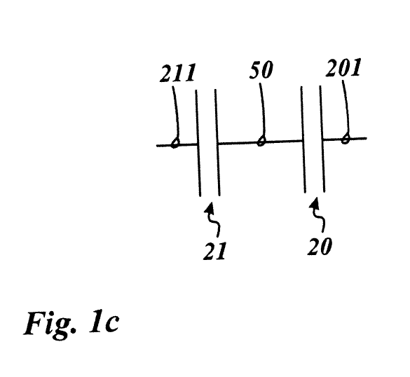

FIG. 1a shows a diagrammatic view in section of a first embodiment of an organically electronic circuit according to the invention,

FIG. 1b shows a diagrammatic view in section of a second embodiment of an organically electronic circuit according to the invention,

FIG. 1c shows a diagrammatic equivalent circuit diagram of the first and second embodiments of the organically electronic circuit according to the invention,

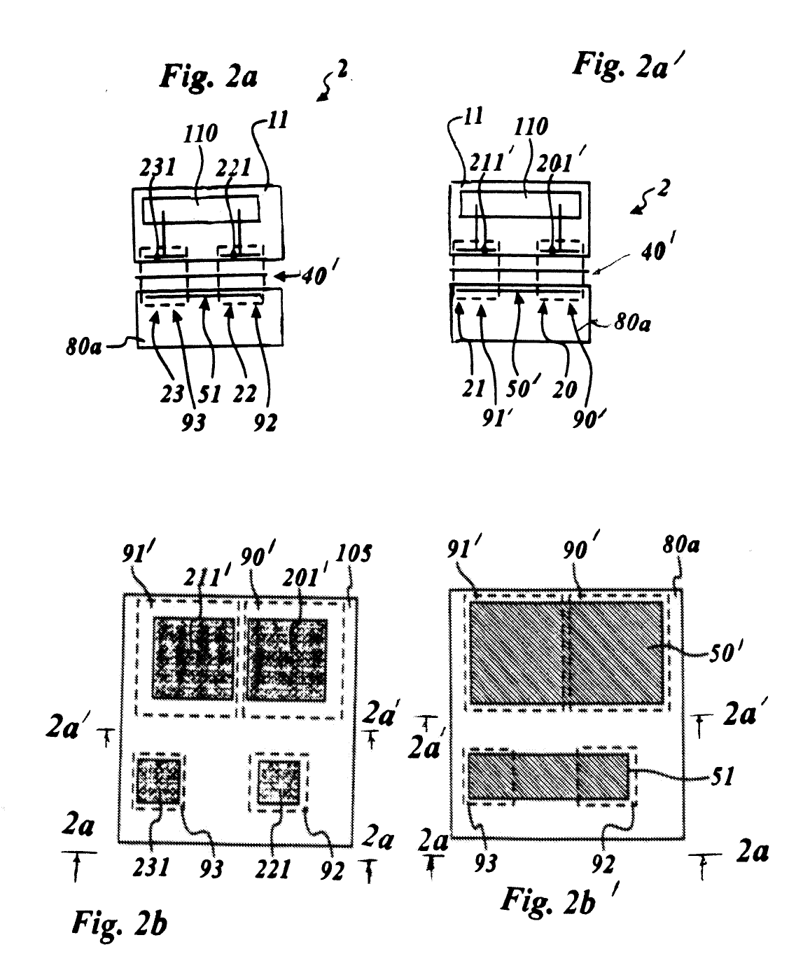

FIG. 2a shows a diagrammatic view in section of a third embodiment of an organically electronic circuit according to the invention,

FIG. 2b is a diagrammatic view from above showing the main substrate and the electrically conducting functional layer as a diagrammatic view from below of the third embodiment of the organically electronic circuit according to the invention,

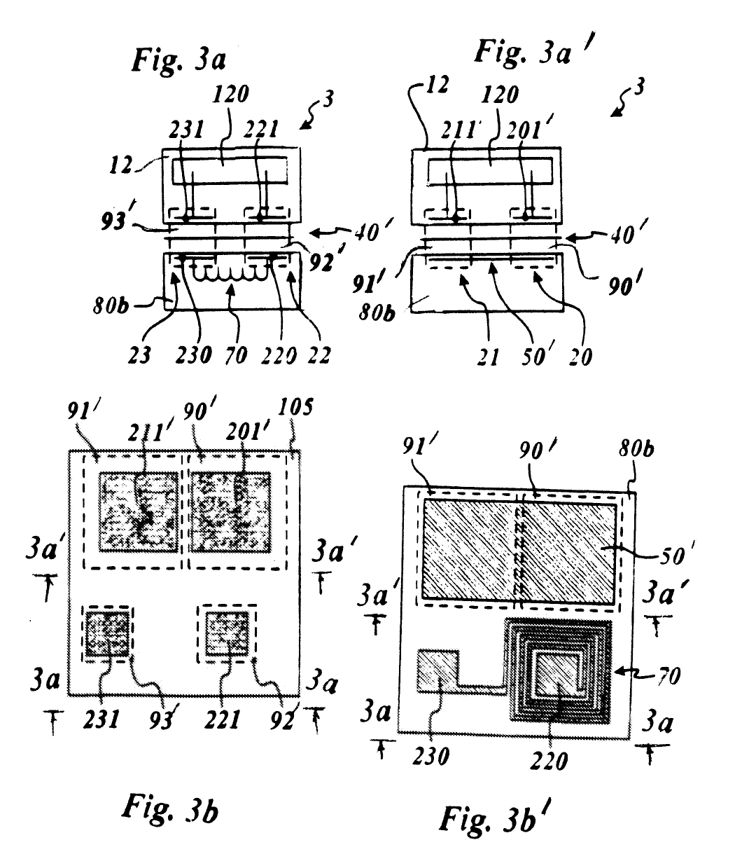

FIG. 3a shows a diagrammatic view in section of a fourth embodiment of an organically electronic circuit according to the invention, and

FIG. 3b is a diagrammatic view from above showing the main substrate and the electrically conducting functional layer as a diagrammatic view from below of the fourth embodiment of the organically electronic circuit according to the invention.

FIG. 1a shows a diagrammatic view in section of a first embodiment of an organically electronic circuit 1 according to the invention. The organically electronic circuit 1 has a main substrate 80 and an organic electronic assembly 10 in the form of a multilayer film body. By way of example for simplicity of the drawing 6 functional layers, namely the functional layers 100, 101, 102, 103, 104 and 105 are shown. The multilayer film body can have a plurality of functional layers. The multilayer film body has one or more electrically conducting functional layers 101, 105 and one or more electrically semiconducting functional layers 103. The functional layers 100, 102 and 104 are in the form of insulation layers in the form of a plastic film. The functional layers 100, 102 and 104 however can also be in the form of conducting or semiconducting functional layers. In a first region 90 of the organically electronic circuit 1 one of the one or more electrically conducting functional layers, namely the functional layer 105, of the organic electronic assembly 10 is shaped as an electrode layer of the electronic assembly 10. An electrode 201 is shaped in that electrically conducting functional layer 105. That electrode 201 can be shaped as an electrode of an organic field effect transistor or an organic diode. That electrically conducting functional layer 105 is further shaped in the form of a first capacitor plate 201. That electrically conducting functional layer 105 thus forms an integral component of the organic electronic assembly 10. In a second region 91 of the organically electronic circuit 1 another of the one or more electrically conducting functional layers, namely the functional layer 101, of the organic electronic assembly 10 is shaped as a further electrode layer of the electronic assembly 10. An electrode 211 is provided in that electrically conducting functional layer 101. That electrode 211, like that of the functional layer 105, can be shaped as an electrode of an organic field effect transistor or an organic diode. That electrically conducting functional layer 211 is further shaped in the form of a second capacitor plate 211. That electrically conducting functional layer 211 thus forms an integrated component of the organic electronic assembly 10. The first capacitor plate 201 and the second capacitor plate 211 comprise Ag, Au or Cu and are of a thickness of 40 nm. The first capacitor plate 201 preferably comprises copper. The second capacitor plate 211 preferably comprises silver. In addition the organically electronic circuit 10 and the main substrate 80 are laminated together. The main substrate 80 has an electrically conductive layer 50. The electrically conductive layer 50 is in the form of a third capacitor plate 50. The electrically conductive layer 50 is in the form of a thin metal film of Al or Cu and is of a thickness of about 18 μm. The third capacitor plate 50 is so shaped and the electronic assembly 10 and the main substrate 80 are so laminated together that the third capacitor plate 50 completely overlaps the first capacitor plate 201 and the second capacitor plate 211. The third capacitor plate 50 overlaps the first region 90 and the second region 91 over the full surface area thereof. The first capacitor plate 201, the second capacitor plate 211 and the third capacitor plate 50 form a capacitor of the organically electronic circuit 1. FIG. 1c is shows a diagrammatic equivalent circuit diagram of the capacitor formed from the first capacitor plate 201, the second capacitor plate 211 and the third capacitor plate 50. The capacitor is therefore formed by series connection of a plate capacitor which is formed by the first capacitor plate 201 and the third capacitor plate 50, with a further plate capacitor formed by the third capacitor plate 50 and the second capacitor plate 211. In the organically electronic circuit 1 the first capacitor plate 201 and the second capacitor plate 211 are shaped in different electrically conducting functional layers 101 and 105 respectively of the one or more electrically conducting functional layers of the electronic assembly 10.

The first region 90 of the organically electronic circuit 1 and the second region 91 of the organically electronic circuit 1, in particular the first capacitor plate 201 and the second capacitor plate 211, are arranged in mutually spaced relationship at a spacing of less than 200 μm. A small spacing of the first region 90 in relation to the second region 91 reduces the induction of unwanted electrical currents in the capacitor. The quality of the organically electronic circuit is thereby improved in comparison with structures whose first and second capacitor plates are at a greater spacing in comparison therewith.

The main substrate 80 is laminated to the organically electronic assembly 10 with the interposition of an insulation layer 40. An insulation layer 40 is arranged between the first capacitor plate 201 and the third capacitor plate 50 and between the second capacitor plate 211 and the third capacitor plate 50. The insulation layer 40 overlaps the first capacitor plate 201, the second capacitor plate and the third capacitor plate 50 completely. For the production of organically electronic circuits it is convenient for the organically electronic circuit 1 to be of a small volume and/or a small surface area. That is advantageous if the organically electronic circuit 1 is in the form of an RFID transponder or a subcircuit of an RFID transponder. The insulation layer 40 is therefore made from an electrically non-conducting tough, dielectric plastic film of a relative dielectric constant of between 2.3 (PP) and 3.2 (PET). The insulation layer 40 comprising the tough plastic film makes it possible for the organically electronic circuit 1 to be suitable for the production of flexible RFID transponders which can be mechanically loaded. Mechanically loadable means that the organically electronic circuit is deformable without defects occurring at the organically electronic circuit, that is to say the organically electronic circuit 1 remains operable even under a mechanical loading. The expression under a mechanical loading is used to mean in particular a mechanical deformation loading and a pressure loading. So that the capacitor formed from the first capacitor plate 201, the second capacitor plate 211 and the third capacitor plate 50 is of a small volume but nonetheless has a large capacitance the insulation layer 40 is of a thickness of about 1 μm. The plastic film of the insulation layer 40 is a multilayer film body which includes in particular a PET film and a PP film.

In addition the organically electronic circuit 1 has a first adhesive layer 32 between the third capacitor plate 50 and the insulation layer 40. Furthermore the organically electronic circuit 1 also has a second adhesive layer 31. The second adhesive layer 31 is between the first capacitor plate 201 and the insulation layer 40 and between the second capacitor plate 211 and the insulation layer 40. The first adhesive layer 32 and the second adhesive layer 31 are connected over the full surface area to the insulation layer 40. The first adhesive layer 32 and the second adhesive layer 31 can be produced by applying a multiplicity of adhesive dots comprising an adhesive to the third capacitor plate 50 and the functional layer 105 respectively. The adhesive is electrically non-conducting, non-corroding and produces a tough adhesive layer after hardening. In addition the first adhesive layer 32 and the second adhesive layer 31 have a relative dielectric constant of preferably between 2 and 3. The first adhesive layer 32 and the second adhesive layer 31 are of a thickness of about 1 μm. Those properties of the first adhesive layer 32 and the second adhesive layer 31 make it possible to form small and mechanically robust capacitors having a high capacitance.

In particular it is possible for the first adhesive layer 31, the second adhesive layer 32 and/or the insulation layer 40 to be replaced by an electrically insulating lacquer layer.

For further mechanical stabilisation the main substrate 80 has a substrate layer 60. In that respect the substrate layer 60 comprises paper and a plastic film.

As already generally described the organically electronic circuit 1 has an organic electronic assembly 10 which fundamentally differs in the materials and production processes used from a conventional silicon chip used for integrated circuits. The electrically conducting, semiconducting and/or insulating functional layers 101, 102, 103, 104 and 105 of the electronic assembly 10 are formed by layers of a multilayer film body. The layers are applied by printing, coating with a doctor blade, vapor deposition or sputtering. The electrically conducting, semiconducting and/or insulating functional layers 100, 101, 102, 103, 104 and 105 of the organic electronic assembly 10 are in this case, in contrast to a silicon chip, built up on a flexible carrier substrate comprising a plastic film and/or paper of a thickness of between 10 μm and 100 μm. That film forms the carrier substrate of the integrated electronic circuit, that is to say the electronic assembly 10 instead of a silicon dioxide wafer in the case of conventional silicon chip technology. The semiconducting functional layers of that organically electronic circuit are preferably applied in a solution and are thus applied for example by printing, spraying, coating with a doctor blade or casting. In that respect, preferably semiconducting functional polymers such as polythiophene, polyterthiophene, polyfluorine, pentacene, tetracene, oligothothene, inorganic silicon embedded in a polymer matrix, nano-silicon or polyarylamine are used as materials of the semiconducting functional layers. Inorganic materials can equally be used. The inorganic materials can be applied in solution or by sputtering or by vapor deposition. Preferred inorganic materials are for example ZnO or a-Si.

FIG. 1b shows a diagrammatic view in section of a second embodiment of an organically electronic circuit 1 according to the invention. The second embodiment of an organically electronic circuit 1 according to the invention is an embodiment which is modified in relation to the first embodiment. In contrast to the first embodiment according to the invention the organically electronic circuit 1 has the first capacitor plate 201 and the second capacitor plate 211 in the same electrically conducting functional layer 105. The first capacitor plate 201 and the second capacitor plate 211 are therefore shaped in the same electrically conducting functional layer 105. In addition the first capacitor plate 201 and the second capacitor plate 211 are of differing sizes. This is in contrast to the first embodiment according to the invention in which the two capacitor plates 201 and 211 are shaped with the same size. Furthermore the first region 90 and the second region 91 and in particular the first capacitor plate 201 and the second capacitor plate 211 are also spaced at a smaller spacing relative to each other than is the case with the first embodiment according to the invention.

FIG. 2a shows a diagrammatic sectional view of a third embodiment of an organically electronic circuit 2 according to the invention. The third embodiment has a second capacitor which can be implemented in a similar manner to the first two embodiments. FIG. 2a shows an organically electronic circuit 2 including an organic electronic assembly 11. In a third region of the organically electronic circuit 2 the organic electronic assembly 11 has an electrically conducting functional layer of the organic electronic assembly 11. The electrically conducting functional layer is in the form of an electrode layer of the electronic assembly 11. An electrode for an organic field effect transistor or an organic diode is shaped in that electrode layer. That electrically conducting functional layer is further shaped in the form of a further first capacitor plate 221. That first capacitor plate 221 thus forms an integral component of the organically electronic circuit 2. In a fourth region 93 of the organically electronic circuit 2 the organic assembly 11 has an electrically conducting functional layer of the organic electronic assembly 11. That electrically conducting functional layer is also in the form of an electrode layer of the electronic assembly 11. An electrode for an organic field effect transistor or an organic diode is shaped in that electrode layer. That electrically conducting functional layer is further shaped in the form of a further second capacitor plate 231. The further second capacitor plate 231 thus also forms an integrated component of the organically electronic circuit 2. The main substrate 80a has an electrically conductive layer. The electrical conductive layer is shaped in the form of a further third capacitor plate 51. The third capacitor plate 51 is so shaped and the organic electronic assembly 11 and the main substrate 80a are so laminated together that the further third capacitor plate 51 completely overlaps the further first capacitor plate 221 and the further second capacitor plate 231. In a modified embodiment which is not shown however it is also possible to provide for partial overlap. The further first capacitor plate 221, the further second capacitor plate 231 and the further third capacitor plate 51 form a further capacitor of the organically electronic circuit 2.

It is possible in that way to produce an organically electronic circuit having one or more capacitors which are implemented by those three capacitor plates. Similarly to the first and second embodiments according to the invention the further first and further second capacitor plates can be provided in the same or in different functional layers of the organic electronic assembly.

FIG. 2b is a diagrammatic view from above showing the main substrate 80a and the electrically conducting functional layer 105 as a diagrammatic view from below of the third embodiment of the organically electronic circuit 2 according to the invention. The third capacitor plate 50 and the further third capacitor plate 51 are of a strip shape of differing length and width in the main substrate 80a. The third capacitor plate 50 and the further third capacitor plate 51 are both provided in the same electrically conducting functional layer and are both of the same thickness.

The third capacitor plate 50 is of a large area and is of an area of between 25 mm² and 150 mm², preferably being 100 mm². The further third capacitor plate however is substantially smaller, involving an area of less than 50 mm². In addition FIG. 2b shows the first capacitor plate 201 and the second capacitor plate 211 are both of a large area, of an area of between 12 mm² and 75 mm², preferably being 50 mm². In an embodiment according to the invention which is not shown however it can be provided that the first capacitor plate 201 and the second capacitor plate 211 can be different and in particular can be of differing sizes. FIG. 2b in conjunction with FIG. 2a clearly shows how the two capacitors are produced in a circuit with a full-area insulation layer 40, namely the first capacitor plate 201, the second capacitor plate 211 and the third capacitor plate 50 form the first capacitor, while the further first capacitor plate 221, the further second capacitor plate 231 and the further third capacitor plate 51 form the further capacitor.

FIG. 3a shows a diagrammatic sectional view of a fourth embodiment of an organically electronic circuit 3 according to the invention. The organically electronic circuit 3 is in the form of an RFID transponder. In a manner corresponding to the preceding embodiments the organically electronic circuit 3 has a capacitor formed from the first capacitor plate 201, the second capacitor plate 211 and the third capacitor plate 50 with the interposition of an insulation layer 40 over the full surface area thereof. A coil 70 is capacitively coupled to an organic electronic assembly 12 to embody the RFID transponder. The capacitive coupling is now illustrated by reference to FIG. 3b.

FIG. 3b shows a diagrammatic view from above of the main substrate 80b and the electrically conducting functional layer 105 in a diagrammatic view from below of the fourth embodiment of the organically electronic circuit 3 according to the invention. The organically electronic circuit 3 has a flat helical coil 70. The coil 70 is arranged in the main substrate 80b. At its beginning and its end the coil 70 further has a beginning plate 220 and an end plate 230 respectively. The material of the coil 70 is a metal or a metal alloy. Preferably the coil 70 comprises the same material as the third capacitor plate 50. The coil 70 and the third capacitor plate 50 are arranged in the same plane of the main substrate 80b and are of the same thickness. The coil 70 represents an antenna coil of the RFID transponder 3. The antenna oscillator circuit comprises the coil 70 with its beginning plate 220 and its end plate 230 and a further first capacitor plate 221 and a further second capacitor plate 231. The antenna oscillator circuit of the RFID transponder 3 is produced by lamination of the organic electronic assembly 12 on the main substrate 80b with an interposed insulation layer 40. In that arrangement the beginning plate 220 with the first further capacitor plate 221 forms a first oscillator circuit capacitor 22 and the end plate 230 with the first further capacitor plate 231 forms a second oscillator circuit capacitor 23. The antenna oscillator circuit has the coil 70 and the two oscillator circuit capacitors 22 and 23. The antenna oscillator circuit is produced by capacitive coupling of the coil 70 with its beginning plate 220 and its end plate 230 to the organic electronic assembly 12. The antenna oscillator circuit of the RFID transponder is produced by lamination of the main substrate 80b with the organically electronic circuit 3, with the interposition of the insulation layer 40 over the full surface area.

A common feature of the preferred embodiments according to the invention of the organically electronic circuit, which are described with reference to FIGS. 1a through 3b, is the interposition of an insulation film 40 comprising a tough plastic film. That insulation film reduces the rejection proportion, caused by production considerations, of organically electronic circuits by increases in mechanical load-bearing capability of the organically electronic circuits.

In addition the organic electronic assembly 10, 11 and/or 12 of the foregoing embodiments have an organically electronic circuit 1, 2 and/or 3, preferably with a plurality of organic components selected from the group of organic resistor, organic capacitor, organic diode and/or organic field effect transistor.

1. An organic electronic circuit, comprising:
a main substrate; and
an organic electronic assembly in the form of a multilayer film body which has one or more electrically conducting functional layers and one or more electrically semiconducting functional layers;
wherein in a first region of the organic electronic circuit one of the one or more electrically conducting functional layers of the organic electronic assembly is shaped in the form of a first capacitor plate forming an integral component of the organic electronic assembly;
said one or more electrically conducting functional layers has an electrode layer of the electronic assembly in which electrode layer one or more electrodes for one or more organic field effect transistors or organic diodes are formed; and
in a second region of the organic electronic circuit one of the one or more electrically conducting functional layers of the organic electronic assembly, which has an electrode layer of the electronic assembly in which one or more electrodes for one or more organic field effect transistors or organic diodes are formed, is further shaped in the form of a second capacitor plate which forms an integrated component of the organic electronic assembly;
wherein the electronic circuit and the main substrate are laminated together;
wherein the main substrate has an electrically conductive layer shaped as a third capacitor plate, and
the third capacitor plate is so shaped and the electronic assembly and the main substrate are so laminated together that the third capacitor plate at least partially overlaps the first capacitor plate and the second capacitor plate respectively, and
wherein the first capacitor plate, the second capacitor plate and the third capacitor plate form a pair of capacitors of the organic electronic circuit.

2. The organic electronic circuit as set forth in claim 1 wherein the third capacitor plate overlaps the first region and the second region over the full surface area thereof.

3. The organic electronic circuit as set forth in claim 1 wherein the third capacitor plate is strip-shaped.

4. The organic electronic circuit as set forth in claim 1 wherein the first capacitor plate and the second capacitor plate are shaped in the same electrically conducting functional layer of the one or more electrically conducting functional layers of the electronic assembly.

5. The organic electronic circuit as set forth in claim 1 wherein the first capacitor plate and the second capacitor plate are shaped in different electrically conducting functional layers of the one or more electrically conducting functional layers of the electronic assembly.

6. The organic electronic circuit as set forth in claim 1 wherein the first region of the organic electronic circuit and the second region of the organic electronic circuit are so arranged relative to each other that the first capacitor plate and the second capacitor plate are spaced from each other at less than 100 pm.

7. The organic electronic circuit as set forth in claim 1 wherein the first capacitor plate, the second capacitor plate and/or the third capacitor plate are each of a surface area of between 4 mm² and 100 mm2.

8. The organic electronic circuit as set forth in claim 1 wherein
an insulation layer is between the first capacitor plate and the third capacitor plate, and between the second capacitor plate and the third capacitor plate, and
the insulation layer completely overlaps the first capacitor plate and the second capacitor plate, and/or
the insulation layer completely overlaps the third capacitor plate.

9. The organic electronic circuit as set forth in claim 8 wherein the insulation layer comprises an inorganic dielectric layer with a layer thickness of between 5 and 100 nm.

10. The organic electronic circuit as set forth in claim 9 wherein the insulation layer is arranged on the surface of the electrically conductive layer of the main substrate and an adhesive layer is between the insulation layer and the electronic assembly.

11. The organic electronic circuit as set forth in claim 10 wherein the insulation layer is applied to the surface of the electrically conductive layer of the main substrate by a coating process.

12. The organic electronic circuit as set forth in claim 10 wherein the insulation layer comprises a metal oxide of a layer thickness of between 5 and 10 nm and is produced by surface oxidation of the electrically conductive layer of the main substrate, that comprises a metallic material.

13. The organic electronic circuit as set forth in claim 8 wherein the insulation layer comprises an electrically non-conducting plastic, in particular an electrically non-conducting plastic film or an electrically non-conducting plastic lacquer.

14. The organic electronic circuit as set forth in claim 1 wherein the third capacitor plate is in the form of a metal film.

15. The organic electronic circuit as set forth in claim 1 wherein the first capacitor plate, the second capacitor plate and/or the third capacitor plate comprises a material selected from the group Al, Cu, Ag, Au and Fe.

16. The organic electronic circuit as set forth in claim 1 wherein the first capacitor plate, the second capacitor plate and/or the third capacitor plate is of a thickness of between 10 nm and 100 nm.

17. The organic electronic circuit as set forth in claim 8 wherein
the organic electronic circuit has a first adhesive layer between the third capacitor plate and the insulation layer, and/or
the organic electronic circuit has a second adhesive layer between the first capacitor plate and the insulation layer and between the second capacitor plate and the insulation layer.

18. The organic electronic circuit as set forth in claim 17 wherein the first adhesive layer and/or the second adhesive layer is dielectric and has a relative dielectric constant of between 2 and 3.

19. The organic electronic circuit as set forth in claim 17 wherein the first adhesive layer and/or the second adhesive layer is of a thickness of between 0.5 μm and 20 μm.

20. The organic electronic circuit 1, 2, 3) as set forth in claim 8 wherein the insulation layer is dielectric and has a relative dielectric constant of between 2 μm and 7 μm.

21. The organic electronic circuit as set forth in claim 8 wherein the insulation layer is of a thickness of between 0.9 μm and 10 μm.

22. The organic electronic circuit as set forth in claim 8 wherein the insulation layer is a plastic film.

23. The organic electronic circuit as set forth in claim 1 wherein the main substrate has a substrate layer comprising at least one of paper and a plastic film.

24. The organic electronic circuit as set forth in claim 1 wherein
the organic electronic assembly has one or more third regions and one or more fourth regions of the organic electronic circuit and, wherein in said one or more third regions, the organic electronic assembly has a respective one of the one or more electrically conducting functional layers of the organic electronic assembly that is an electrode layer of the electronic assembly, in which one or more electrodes for one or more organic field effect transistors or organic diodes are formed, is further shaped in the form of a further first capacitor plate, which forms an integral component of the organic electronic circuit, and in one or more of the fourth regions of the organic electronic circuit, a respective one of the one or more electronically conducting functional layers of the organic electronic assembly is an electrode layer of the electronic assembly, in which one or more electrodes for one or more organic field effect transistors or organic diodes are formed, is further shaped in the form of a further second capacitor plate which forms an integrated component of the organic electronic circuit,
the main substrate has an electronically conductive layer shaped as one or more further third capacitor plates and each of the further one or more third capacitor plates is so shaped and the organic electronic assembly and the main substrate are so laminated together that the respective further third capacitor plate at least partially overlaps the respective further first capacitor plate and the respective further second capacitor plate,
and the further first capacitor plate, the further second capacitor plate and the further third capacitor plate respectively form a further pair of capacitors of the organic electronic circuit.

25. The organic electronic circuit as set forth in claim 1 wherein the organic electronic circuit includes a coil arranged in the main substrate.

26. The organic electronic circuit as set forth in claim 1 wherein the organic electronic assembly has a plurality of organic components selected from the group of organic resistor, organic capacitor, organic diode and/or organic field effect transistor.

27. The organic electronic circuit as set forth in claim 1 wherein the organic electronic circuit includes a rectifying assembly.

28. The organic electronic circuit as set forth in claim 1 wherein the organic electronic circuit is an RFID transponder.

29. A capacitor arrangement comprising:
a substrate;
on the substrate a first electrically conductive capacitor plate;
an insulation layer on the substrate juxtaposed with and on the first electrically conductive capacitor plate; and
on the insulation layer and juxtaposed with the first electrically conductive capacitor plate, second and third electrically isolated coplanar capacitor plates;
wherein the first, second and third capacitor plates form a series connected pair of capacitors.

30. A capacitor arrangement comprising:
a substrate;
on the substrate first and second electrically conductive electrically isolated capacitor plates;
an insulation layer on the substrate and juxtaposed with and on the first and second electrically conductive capacitor plates; and
on the insulation layer and juxtaposed with the first electrically conductive capacitor plate, third and fourth electrically isolated capacitor plates and on the insulation layer and juxtaposed with the second electrically conductive capacitor plates fifth and sixth capacitor plates, all of the third, fourth, fifth an sixth capacitor plates being coplanar;
wherein the first, third and fourth capacitor plates form a first series connected pair of capacitors and the second, fourth and fifth capacitor plates form a second series of connected pair of capacitors.

31. The capacitor arrangement of claim 30 wherein the first capacitor plate is larger in area in plan view than the second capacitor plate, and both plates are in strip form.
